(19) United States
(12) Patent Application Publication
(10) Pub. No.: US 2026/0318835 A1
(43) Pub. Date: Oct. 15, 2026

(54) CALIBRATION METHOD FOR OPTICAL APPARATUS, ILLUMINATION METHOD, AND OPTICAL APPARATUS

(71) Applicant: Lasertec Corporation, Yokohama (JP)

(72) Inventor: Shunsuke TOYOIZUMI, Yokohama (JP)

(21) Appl. No.: 19/463,736

(22) Filed: Jan. 29, 2026

(30) Foreign Application Priority Data
Feb. 7, 2025 (JP) 2025-018972

(51) Int. Cl. G01N 21/64; G01N 21/95

(52) U.S. Cl. CPC G01N 21/6489; G01N 21/645; G01N 21/9501; G01N 2201/127

(57) ABSTRACT

A calibration method for an optical apparatus including an illumination optical system capable of irradiating a single-crystal wafer with illumination light, and a light detection unit capable of detecting photoluminescence light from the single-crystal wafer based on the illumination light can be provided. The optical apparatus includes an adjustment unit capable of adjusting illumination intensity of the illumination light. The calibration method includes: making the illumination optical system irradiate a calibration sample with the illumination light; making the light detection unit receive photoluminescence light from the calibration sample; acquiring a relationship between a state of the adjustment unit and detected intensity of the photoluminescence light; and determining a calibrated state of the adjustment unit based on the relationship. The calibration sample is made of a polycrystal material made of the same element as that of a base material of the single-crystal wafer.

### INCORPORATION BY REFERENCE

This application is based upon and claims the benefit of priority from Japanese Patent Application No. 2025-018972, filed on Feb. 07, 2025, the disclosure of which is incorporated herein in its entirety by reference for all purposes.

### BACKGROUND

The present disclosure relates to a calibration method for an optical apparatus, an illumination method, and an optical apparatus.

A wafer in which silicon carbide (hereinafter also referred to as SiC) is homoepitaxially grown on a SiC wafer is used as a power semiconductor. There is a method for inspecting such a SiC wafer for detecting defects based on photoluminescence light generated by irradiating the SiC wafer with ultraviolet light. Since the wavelength of photoluminescence is different for each defect, defects can be detected by observing the photoluminescence (see Japanese Unexamined Patent Application Publication No. 2008-275485).

### SUMMARY

In an inspection using photoluminescence, it is necessary to carry out calibration in order to maintain the illumination intensity and the like of the illumination light source, which would otherwise deteriorate according to the time of the use, roughly constant. For the calibration, a sample for the calibration (hereinafter also referred to as a calibration sample) disposed on a stage is used. However, if the calibration sample deteriorates each time the illumination for the calibration is repeated, it is impossible to carry out proper calibration.

The present disclosure has been made in view of the above-described problem, and provides a calibration method for an optical apparatus, an illumination method, an optical apparatus, and the like using a proper calibration sample.

A calibration method for an optical apparatus according to an aspect of an embodiment is a calibration method for an optical apparatus including an illumination optical system capable of irradiating a single-crystal wafer with illumination light, and a light detection unit capable of detecting photoluminescence light from the single-crystal wafer based on the illumination light, in which the optical apparatus includes an adjustment unit capable of adjusting illumination intensity of the illumination light, the calibration method includes: making the illumination optical system irradiate a calibration sample with the illumination light; making the light detection unit receive photoluminescence light from the calibration sample; acquiring a relationship between a state of the adjustment unit and detected intensity of the photoluminescence light; and determining a calibrated state of the adjustment unit based on the relationship, and the calibration sample is made of a polycrystal material made of the same element as that of a base material of the single-crystal wafer.

An illumination method according to an aspect of an embodiment is an illumination method performed by an optical apparatus including an illumination optical system capable of irradiating a single-crystal wafer with illumination light, and a light detection unit capable of detecting photoluminescence light from the single-crystal wafer based on the illumination light, in which the optical apparatus includes an adjustment unit capable of adjusting illumination intensity of the illumination light, the illumination method includes: making the illumination optical system irradiate a calibration sample with the illumination light; making the light detection unit receive photoluminescence light from the calibration sample; acquiring a relationship between a state of the adjustment unit and detected intensity of the photoluminescence light; determining a calibrated state of the adjustment unit based on the relationship; placing the single-crystal wafer on a holding part of the optical apparatus; making the illumination optical system irradiate the single-crystal wafer with the illumination light under a condition that the adjustment unit is in the calibrated state; making the light detection unit receive photoluminescence light from the single-crystal wafer; and determining a defect in the single-crystal wafer based on a result of detection of the photoluminescence light from the single-crystal wafer, and the calibration sample is made of a polycrystal material made of the same element as that of a base material of the single-crystal wafer.

An optical apparatus according to an aspect of an embodiment includes: an illumination optical system capable of irradiating a single-crystal wafer with illumination light; a light detection unit capable of detecting photoluminescence light from the single-crystal wafer based on the illumination light; an adjustment unit capable of adjusting illumination intensity of the illumination light; and a holding part having a first area in which the single-crystal wafer can be placed and a second area in which a calibration sample can be placed, the second area being provided outside the first area, in which the calibration sample is made of a polycrystal material made of the same element as that of a base material of the single-crystal wafer, and the optical apparatus is configured to: make the illumination optical system irradiate the calibration sample with the illumination light; make the light detection unit receive photoluminescence light from the calibration sample; acquire a relationship between a state of the adjustment unit and detected intensity of the photoluminescence light; and determine a calibrated state of the adjustment unit based on the relationship.

According to the present disclosure, it is possible to provide a calibration method for an optical apparatus, an illumination method, an optical apparatus, and the like using a proper calibration sample.

The above and other objects, features and advantages of the present disclosure will become more fully understood from the detailed description given hereinbelow and the accompanying drawings.

### BRIEF DESCRIPTION OF DRAWINGS

FIG. 1 is a diagram for explaining a configuration of an optical apparatus according to an embodiment;

FIG. 2 is a diagram for explaining a configuration of a signal processing unit according to an embodiment;

FIG. 3 is a flowchart showing a calibration method for an optical apparatus according to an embodiment;

FIG. 4 is a graph showing a relationship between lamp opening (or lamp supply power) of an illumination light source and PL detected luminance;

FIG. 5 is a graph showing a relationship between the cumulative time of the use of a lamp of an illumination light source and of PL detected luminance; and

FIG. 6 shows graphs showing changes of PL detected luminance according to the irradiation time of illumination light (excitation light) of a single-crystal SiC substrate and those of a polycrystal SiC substrate for comparison therebetween.

### DESCRIPTION OF EMBODIMENTS

Embodiments according to the present disclosure will be described hereinafter with reference to the drawings. The following description shows embodiments according to the present disclosure, and the scope of the present disclosure is not limited to the below-shown embodiments. In the following description, components/structures assigned the same reference numerals are substantially similar to each other.

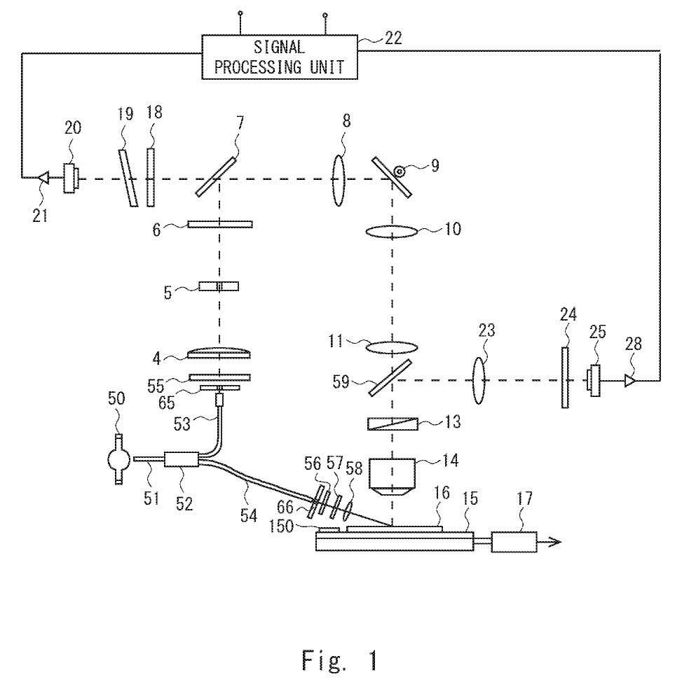

FIG. 1 is a diagram for explaining a configuration of an optical apparatus according to an embodiment. FIG. 1 shows an example of an inspection apparatus for carrying out a calibration method for an optical apparatus and a defect classification method according to an embodiment. In this example, the entire surface of a SiC substrate to be inspected (SiC wafer) is scanned by using a confocal scanning apparatus including a differential interference optical system; reflected light and photoluminescence light (PL light) emitted from the SiC substrate are individually detected; and an inspection of the reflected light and an inspection of the PL light are performed in parallel. A SiC substrate including an epitaxial layer formed thereon is used as an object to be inspected, and defects formed in the epitaxial layer are detected and classified. Note that a SiC substrate including no epitaxial layer formed thereon is also used as an object to be inspected. The SiC substrate may be a 4H-SiC substrate or a 6H-SiC substrate.

In this example, a first illumination system for forming a PL image and a second illumination system for forming a reflection image are used. In the first illumination system, the surface of the substrate is scanned by using an illumination beam in the ultraviolet region. In the second illumination system, the surface of the substrate is scanned by using an illumination beam in the visible region. The first and second illumination beams illuminate the same point on the SiC substrate.

In this example, a reflected-light inspection is performed by using a mercury xenon lamp as an illumination light source 50, and using visible light having a wavelength of 546 nm emitted from the mercury xenon lamp as the illumination beam of the second illumination system. Further, a PL light inspection is performed by using ultraviolet light (UV light) having a wavelength of 313 nm as the illumination beam of the first illumination system. The illumination beam of the first illumination system may be referred to as excitation light. The light beam emitted from the illumination light source 50 propagates through a first optical fiber 51. An optical fiber coupler 52 is coupled to the emission end of the first optical fiber 51. A second optical fiber 53 (for surface observation) and a third optical fiber 54 (for photoluminescence) are coupled to the emission side of the optical fiber coupler 52. The optical beam is divided into two beams by the optical fiber coupler 52. Then, one of the beams propagates through the second optical fiber 53 and is used for the reflected-light inspection, and the other beam propagates through the third optical fiber 54 and is used for the PL light inspection. Note that in some embodiments, a light source for emitting light used for the reflected-light inspection and a light source for emitting light used for the PL light inspection may be separately prepared. In this case, the inspection apparatus does not need to include the optical fiber coupler 52. Note that since the illumination light source could deteriorate according to the cumulative time of the use of the lamp, it is necessary to carry out calibration at regular intervals. Details of the calibration will be described later.

The light beam emitted from the second optical fiber 53 passes through a second adjustment unit 65 and enters a filter 55, which lets light having a wavelength of 546 nm pass therethrough, so that a second illumination beam having a wavelength of 546 nm is emitted therefrom. The second adjustment unit 65 may include a dimmer plate having a plurality of apertures having different sizes. The light beam emitted from the third optical fiber 54 passes through an adjustment unit 66 (which may be referred to as a first adjustment unit 66), passes through a filter 56, which lets light having a wavelength of 313 nm pass therethrough, and enters a polarizer 57. The polarizer 57 receives the light beam and emits a P-polarized light beam. The adjustment unit 66 may include a dimmer plate having a plurality of apertures having different sizes. Therefore, a second illumination beam having a wavelength of 313 nm, which has been P-polarized, is emitted from the polarizer 57. The second illumination beam passes through a focusing lens 58 and is projected toward a SiC substrate 16 as a converging illumination beam.

The first illumination system projects a P-polarized illumination beam toward the SiC substrate 16 at an incident angle equal to the Brewster angle. Therefore, the optical axes of the third optical fiber 54, the filter 56, the polarizer 57, and the lens 58, which constitute the first illumination system, are disposed (i.e., aligned) at an angle equal to the Brewster angle. When the P-polarized illumination beam is projected at the incident angle equal to the Brewster angle, the reflected light becomes substantially zero, so that most of the illumination beam incident on the SiC substrate 16 enters the SiC substrate 16. Therefore, PL light having higher intensity can be generated, and a clear PL image is thereby formed. As a result, the accuracy of the detection of a defect image is increased, so that an advantage that defects are accurately classified is achieved.

The second illumination beam emitted from the filter 55 is converted into a collimated beam by the condensing lens 4, and enters the slit 5. The slit 5 is disposed at the pupil position of the lens 4, and has a slender opening extending in a first direction (a direction perpendicular to the paper surface). Note that the first direction is referred to as an X-direction. The width of the opening of the slit 5 is set to, for example, 10 to 20 μm. Therefore, a slender line-shaped light beam extending in the first direction is emitted from the slit 5. The line-shaped light beam emitted from the slit 5 enters a polarizer 6 and is converted into polarized light having a single plane of vibration (hereinafter also referred to as a vibration plane). This line-shaped polarized light beam is reflected by a half-silvered mirror 7, which functions as a beam splitter, and then passes through a lens 8 and enters a vibrating mirror 9, which functions as a scanning device.

When the surface image of the SiC substrate 16 is reviewed, the vibrating mirror 9 functions as a beam scanning device that deflects the illumination beam in a second direction (Y-direction) perpendicular to the first direction. The entire surface of the SiC substrate 16 is scanned by two dimensional movements of a stage 15, which supports the SiC substrate 16, during the inspection, so that the vibrating mirror 9 functions as a total reflection mirror during the inspection. In this specification, the stage 15 is also referred to as a holding part. Regarding the holding part, an object to be inspected may be held by, instead of the stage 15, a suitable method such as a robot arm or a mechanism for sandwiching the object to be inspected. Therefore, in this specification, the term "placing" may be replaced with "holding" as appropriate. The line-shaped light beam emitted from the vibrating mirror 9 enters the dichroic mirror 59 through the lenses 10 and 11. The dichroic mirror 59 performs a function for separating the reflected light and the PL light emitted from the SiC substrate 16. Therefore, for example, a dichroic mirror that lets light having a wavelength of 546 nm ±20 nm pass therethrough and reflects light having other wavelengths is used. The illumination beam, which passed through the dichroic mirror 59, enters a Nomarski prism 13. In this example, the Nomarski prism 13 is used as a differential interference optical system. The line-shaped illumination beam, which has entered the Nomarski prism 13, is converted into two sub-beams whose vibration planes are perpendicular to each other. These two sub-beams have a phase difference expressed as (2m+1)π/2 therebetween, where m is a natural number. Therefore, a defect having a height change of several nanometers formed on the surface of the SiC substrate 16 can be detected as a light/dark luminance image. Further, the shirring amount of the Nomarski prism 13 is set to, for example, 2 μm. Note that the Nomarski prism 13 is detachably disposed in the optical path, so that it is inserted into the optical path when a confocal differential interference image of the SiC substrate 16 is taken, and is removed from the optical path at all other times, for example, when a three-dimensional confocal image of the SiC substrate 16 is taken or a surface contour image of the SiC substrate 16 is taken.

The two sub-beams exiting from the Nomarski prism 13 enter an objective lens 14. The objective lens 14 converges the two line-shaped sub-beams, which have entered therein, and projects them toward the SiC substrate 16 disposed on the stage 15. In this example, a SiC substrate 16 including an epitaxial layer formed thereon is used as a substrate to be inspected, and defects present in the epitaxial layer are detected. The stage 15 is formed by an XY-stage; its position information is detected by a position sensor 17; and the position information of the stage 15 is supplied to a signal processing unit 22. During the inspection, the stage 15 moves in the Y- and X-directions in a zigzag manner, so that the entire surface of the SiC substrate 16 is scanned by the illumination beam. Note that when a detected defect is reviewed by using the address of the defect, the stage is moved in the X- and Y-directions based on the coordinate information of the defect, and the defect is thereby moved into the field of view; and the vibrating mirror 9 is scanned in the second direction, so that a confocal differential interference image of the defect and its vicinity can be taken.

When a defect appears on the surface of the SiC substrate 16 as a concave/convex defect having a size of about several nanometers to several hundred nanometers, a phase difference corresponding to the height change of the defect is introduced between the two sub-beams reflected on the surface of the SiC substrate 16. Consequently, two reflected sub-beams containing phase difference information corresponding to the height of the defect present on the surface of the SiC substrate 16 are formed. These two reflected sub-beams are concentrated by the objective lens 14 and enter the Nomarski prism 13. Then, the two reflected sub-beams are combined by the Nomarski prism 13, so that an interference beam containing the phase difference information indicating the height change on the surface of the SiC substrate 16 is formed. For example, when a concave or convex defect having a size of about several nanometers is present on the surface of the SiC substrate 16, one of the two sub-beams, which have been incident on the surface of the SiC substrate 16, scans the defect, and the other sub-beam scans the normal surface part. Consequently, a phase difference corresponding to the height of the defect is introduced between the two sub-beams. As a result, the defect, which has appeared on the surface of the SiC substrate 16, is detected as a luminance image.

When a crystal defect is present inside the epitaxial layer of the SiC substrate 16, the first illumination beam, which is projected through the lens 58, passes through the surface of the SiC substrate 16, enters the SiC substrate 16, and is incident on the defect. When ultraviolet light is incident on the defect, PL light having a wavelength that varies according to the type of the defect is generated. According to IEC 63068-3 ANNEX B, the wavelength of PL light coming from a BPD (Basal Plane Dislocation), which is a type of defect of the SiC substrate 16, is about 700 nm. An SSF (Shockley-type Stacking Fault), which is another type of defect of the SiC substrate 16, is classified into one of 1SSF to 4SSF. The wavelength of PL light coming from 1SSF is about 420 nm. The wavelength of PL light coming from 2SSF is about 500 nm. The wavelength of PL light coming from 3SSF is about 480 nm. The wavelength of PL light coming from 4SSF is about 455 nm.

The reflected light and the PL light emitted from the SiC substrate 16 are concentrated by the objective lens 14, pass through the Nomarski prism 13, and enter the dichroic mirror 59. The dichroic mirror 59 lets light having a wavelength of 546 nm ±20 nm pass therethrough and reflects light having other wavelengths. Therefore, the PL light generated by a BPD or an SSF is reflected by the dichroic mirror 59. Meanwhile, the reflected light reflected on the surface of the SiC substrate 16 passes through the dichroic mirror 59.

The reflected light, which has passed through the dichroic mirror 59, passes through the lenses 11 and 10, is reflected by the vibrating mirror 9, and enters the lens 8. This lens 8 acts as an image-forming lens for the reflected light coming from the SiC substrate 16. The reflected light, which has passed through the lens 8, passes through the half-silvered mirror 7, passes through an analyzer 18 and a positioner 19, and enters the second light detection means 20 (for surface observation). In this example, the second light detection unit 20 is formed by a line sensor. In other example, the second light detection means 20 may be an area camera. An image signal output from the line sensor, which serves as a photographing device, is supplied to the signal processing unit 22 through the amplifier 21.

The PL light reflected on the dichroic mirror 59 enters a filter 24 through a lens 23. The filter 24 lets light having wavelengths including a visible region and an infrared region pass therethrough. The infrared region means a wavelength range longer than 700 nm.

The filter 24 lets at least light having the wavelength of the PL light of the SSF and light having the wavelength of the PL light of the BPD. The light-emission intensity of the PL light coming from 1SSF, 2SSF, 3SSF, or 4SSF has a peak in a range of 420 to 500 nm, and the wavelength of the PL light coming from a BPD has a peak at about 700 nm. Therefore, the filter 24 is configured so as to let light having a wavelength of 400 to 520 nm and light having a wavelength of 680 nm or longer pass therethrough.

The first light detection unit 25 (for photoluminescence, also referred to simply as a light detection unit) is formed by a line sensor. In other example, the first light detection unit 25 may be an area camera. The image signal output from the first light detection unit 25 is supplied to the signal processing unit 22 through the amplifier 28.

An illumination optical system capable of irradiating an object to be inspected with a first beam (excitation light) is referred to as a first illumination optical system or simply an illumination optical system. As described above, the first illumination optical system (simply referred to as the illumination optical system) may include optical elements such as the third optical fiber 54, the filter 56, the polarizer 57, and the lens 58 in addition to the illumination light source 50.

An illumination optical system capable of irradiating an object to be inspected with a second beam to be reflected on the surface of the object to be inspected is referred to as a second illumination optical system. As described above, the second illumination optical system may include optical elements such as the second optical fiber 53, the filter 55, the lens 4, the slit 5, the polarizer 6, the half mirror 7, the lens 8, the vibrating mirror 9, the lens 10, the lens 11, the Nomarski prism 13, and the objective lens 14 in addition to the illumination light source 50.

The first illumination optical system and the second illumination optical system are just classified according to the purpose and the function. Therefore, cases where some or all of the optical elements included in the first illumination optical system are also used in the second illumination optical system are not excluded. Similarly, cases where some or all of the optical elements included in the second illumination optical system are also used in the first illumination optical system are not excluded.

The light detection unit 25 capable of receiving photoluminescence light from the object to be inspected is referred to as the first light detection unit 25 or simply the light detection unit 25. The light detection unit 20 capable of receiving reflected light from the surface of the object to be inspected is referred to as the second light detection unit 20.

The first light detection unit 25 and the second light detection unit 20 are just classified according to the purpose and the function. Therefore, cases where the first light detection unit 25 and the second light detection unit 20 are formed by the same sensor substrate are not excluded.

The adjustment unit 66 can adjust the illumination intensity of the first illumination light (first beam, i.e., excitation light). As described above, the adjustment unit 66 can include a dimmer plate having a plurality of apertures having different sizes. In this case, the adjustment unit 66 can adjust the illumination intensity of the first illumination light by changing the position of an adjustment plate (i.e., by selecting which of the apertures having different sizes the light that has passed through the third optical fiber 54 should pass through). Further, the adjustment unit 66 may also include a controller for controlling the power supplied to the light source 50 belonging to the first illumination optical system. In this case, the adjustment unit 66 can adjust the illumination intensity of the first illumination light by changing the target amount of the power supplied to the light source belonging to the first illumination optical system set by the controller.

As will be described later, it is possible to, by adjusting the state of the adjustment unit 66, use the intensity of the photoluminescence light generated from the calibration sample irradiated with the first illumination light, detected by the first light detection unit 25 (i.e., PL detected luminance) as PL detected luminance in a predetermined range. The state of the adjustment unit 66 when the intensity of the photoluminescence light generated from the calibration sample irradiated with the first illumination light, detected by the first light detection unit 25 (i.e., PL detected luminance) is PL detected luminance in the predetermined range is referred to as a calibrated state. That is, when the state of the adjustment unit 66 is the calibrated state, the PL detected luminance of the photoluminescence light generated from the calibration sample irradiated with the first illumination light, detected by the first light detection unit 25 has a value in the predetermined range. Further, it is expected that when the state of the adjustment unit 66 is the calibrated state, the PL detected luminance of the photoluminescence light generated from the single-crystal SiC irradiated with the first illumination light, detected by the first light detection unit 25 has a value in the predetermined range.

The second adjustment unit 65 can adjust the illumination intensity of the second illumination light (second beam). As described above, the second adjustment unit 65 may include a dimmer plate having a plurality of apertures having different sizes. In this case, the second adjustment unit 65 can adjust the illumination intensity of the second illumination light by changing the position of the adjustment plate (i.e., by selecting which of the apertures having different sizes the light that has passed through the second optical fiber 53 should pass through). The second adjustment unit 65 may include a controller for controlling the power supplied to the light source 50 belonging to the second illumination optical system. In this case, the second adjustment unit 65 can adjust the illumination intensity of the second illumination light by changing the target amount of the power supplied to the light source belonging to the second illumination optical system set by the controller. Note that as described above, the light source 50 belonging to the first illumination optical system and the light source 50 belonging to the second illumination optical system may be the same light source or may be different light sources.

It is possible to, by adjusting the state of the adjustment unit 65, use the intensity of the reflected light generated from the sample irradiated with the second illumination light, detected by the second light detection unit 20 as detected intensity in a predetermined range. The state of the second adjustment unit 65 when the intensity of the reflected light generated from the sample irradiated with the second illumination light, detected by the second light detection unit 20 is detected intensity in the predetermined range is referred to as a calibrated state. That is, when the state of the second adjustment unit 65 is the calibrated state, the intensity of the reflected light generated from the sample irradiated with the second illumination light, detected by the second light detection unit 20 has a value in the predetermined range.

Note that the optical apparatus includes, for example, a microcomputer including a CPU (Central Processing Unit) for performing arithmetic processing and the like, a memory including a ROM (Read Only Memory) and a RAM (Random Access Memory) in which arithmetic programs and the like executed by the CPU are stored, and an interface unit (I/F) for receiving and outputting signals from and to the outside. The CPU, the memory, and the interface unit are connected to each other through a data bus and the like. The operations of various components can be controlled by the microcomputer.

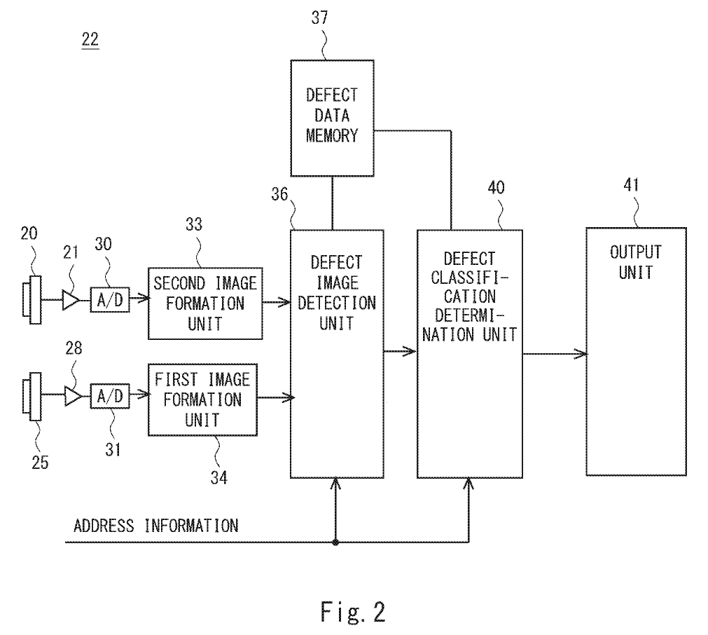

FIG. 2 shows an example of the signal processing unit 22. In this example, the detection of defects by a reflected-light inspection and the detection of defects by a PL-light inspection are performed in parallel, and the detected defects are classified based on the results of these inspections. Image signals output from the second light detection unit 20 and the first light detection unit 25 are supplied to A/D converters 30 and 31, respectively, and converted into digital signals.

A two-dimensional image (reflection image) formed by reflected light is formed by supplying an image signal output from the second light detection unit 20 (for surface observation) to a second image formation unit 33. A two-dimensional image (PL image) formed by PL light including a visible region is formed by supplying a first image signal output from the first light detection unit 25 (for photoluminescence) to a first image formation unit 34.

The reflection image signal and the PL image signal are supplied to a defect image detection unit 36. The defect image detection unit 36 compares the input reflection image signal and the PL image signal with a reference luminance value on a pixel-by-pixel basis, detects a pixel(s) indicating a luminance value outside the range of the reference luminance value, and forms a defect image. For example, a defect image is formed by mapping pixels outside the range of the reference luminance value. A defect image may be detected by mapping pixels in each of which an image signal having a luminance higher than a reference value is detected.

Address information indicating the position on the SiC substrate 16 at which the illumination beam is incident is also supplied to the defect image detection unit 36. This address information may be determined by using the position information of the stage 15, which supports the SiC substrate 16, and information of each pixel in the second light detection unit 20 and the first light detection unit 25. The detected defect image is stored in a defect data memory 37 together with the address information. After the inspection over the entire surface of the SiC substrate 16 is completed, an operator can access the defect data memory 37 by using the address of a defect of interest, and thereby can display and observe the defect image on the monitor.

The detected defect image is supplied to a defect classification determination unit 40. When a triangular defect image is detected in the reflection image, the defect classification determination unit 40, which is also referred to as simply a determination unit, classifies the defect as a 3C-SF (also referred to as poly-inclusion). The defect classification determination unit may classify the defect as a 3C-SF by taking the fact that a particle is present at the apex of the triangle into consideration.

The defect classification determination unit 40 may classify a defect that appears as a triangular defect image on the reflection image and appears as a dark triangular defect image in the PL image as a 3C-SF. When the peak wavelength of PL light coming from a 3C-SF is not included in the transmission wavelength range of the filter 24, the defect image of the 3C-SF on the PL image becomes dark against the background.

When a bright triangular defect image is detected on the PL image, the defect classification determination unit 40 classifies this defect as an SSF. The SSF includes 1SSF to 4SSF. Since the filter 24 lets PL light coming from an SSF pass therethrough, the defect image of the SSF on the PL image becomes bright against the background.

In the related art, since the filter 24 does not let PL light coming from an SSF, the SSF is detected as a dark triangular region. However, there is a problem that the detection accuracy is poor because the contrast is low. In the embodiment, the filter 24 that lets PL light coming from an SSF pass therethrough is used, so that the accuracy of the detection of an SSF can be improved.

Note that when a defect image having a quadrangular shape (e.g., a trapezoid or a diamond shape) is detected on the PL image, the defect classification determination unit 40 may classify this defect as an SSF. It has been known that a BPD may grow into an SSF, and in this case, a defect image having a quadrangular shape may be detected on the PL image. Since the contrast of the defect image is improved, the embodiment can make it possible to detect an SSF originating from a BPD.

Although it is difficult to detect an SSF from a reflection image, the embodiment can make it possible to detect an SSF by using a PL image. The defect classification determination unit 40 may classify a defect as an SSF by taking the fact that a defect image indicating one side or two sides of a triangle is detected on the reflection image into consideration.

The defect classification determination unit 40 may classify the SSF into 1SSF to 4SSF. The defect classification determination unit 40 may classify the SSF into 1SSF to 4SSF based on the result of detection at each wavelength of the PL light.

The defect classification determination unit 40 may classify the SSF into 1SSF to 4SSF based on, for example, the PL image at each wavelength. For example, a spectrum camera may be used as the first light detection unit 25. Alternatively, it is possible to take a PL image at each wavelength by disposing a filter corresponding to the PL wavelength of one of 1SSF to 4SSF between the filter 24 and the first light detection unit 25 shown in FIG. 1. Alternatively, the first light detection unit 25 may be equipped with a prism or a color filter. In this way, the first light detection unit 25 may take a color image, and an SSF may be classified into 1SSF to 4SSF based on the difference in color of each defect image.

When a bright line-shaped defect image is detected on the PL image, the defect classification determination unit 40 classifies this defect as a BPD. Since the filter 24 lets the PL light coming from the BPD pass therethrough, the defect image of the BPD on the PL image becomes bright against the background.

The defect classification determination unit 40 analyzes whether the defect classified as the SSF is an SSF originating from a BPD or an SSF generated during the epitaxial growth. That is, the defect classification determination unit 40 classifies the detected defect as an SSF originating from a BPD or an SSF generated during the epitaxial growth. Specifically, the defect classification determination unit 40 determines that a defect originates from a BPD when one side of a triangle or a quadrangle indicating a defect image of an SSF on the PL image is thicker than the other sides thereof.

The defect classification determination unit 40 may classify each defect based on the result of learning such as deep learning. The defect data memory 37 stores, for each defect image, defect data including a defect classification and an address of the defect image.

The defect classification is supplied to output unit 41 together with the address information. An operator inputs designation information specifying a defect type of interest and an occurrence state through an input device such as a keyboard.

Although the object to be inspected has been described as a SiC substrate in the above description, the object to be inspected is not limited to this example. The object to be inspected may be any substance which can be inspected for a defect(s) by using photoluminescence light, and its examples include a GaN substrate and other compound semiconductor substrates. Further, the wavelength of the light emitted from the light source 50 and the wavelength of the light that passes through or is reflected by the filter 57 or the dichroic mirror 59 may be set to a wavelength different from the aforementioned wavelength as appropriate while taking the purpose of the inspection, the wavelength of the photoluminescence light generated from the object to be inspected, and the like into consideration.

Next, a calibration method for an optical apparatus according to some embodiments will be described.

In the optical apparatus shown in FIG. 1, the calibration sample 150 is disposed in the second area at an outer corner of the stage 15 having the first area in which the sample to be evaluated (e.g., the single-crystal SiC substrate 16) is disposed. For the calibration sample 150, as a substance which has the same photoluminescence emission characteristic as that of the single-crystal SiC substrate 16, which is the sample to be evaluated, that is, for which the wavelength of photoluminescence light generated by excitation light is equal to that of the single-crystal SiC substrate 16, and which hardly deteriorates by excitation light, for example, polycrystal SiC can be used. The polycrystal SiC is a polycrystal material composed of the constituent elements of the single-crystal SiC (i.e., Si and C). Because of the stability of the bond between elements, the polycrystal SiC is less likely to be oxidated by excitation light than the single-crystal SiC is.. Therefore, even when the calibration sample is repeatedly irradiated with excitation light for the calibration, its deterioration is small, so that proper calibration can be continuously performed.

The same can be true when the sample to be evaluated is not the single-crystal SiC substrate 16. That is, when the object to be inspected is a single-crystal substrate (single-crystal wafer) composed of constituent elements different from Si and C, a polycrystal material composed of constituent elements of the single-crystal substrate (single-crystal wafer) may be used as the calibration sample 150. For example, when the object to be inspected is a single-crystal GaN substrate, a polycrystal material composed of Ga and N may be used as the calibration sample 150.

Note that more strictly, a polycrystal material composed of constituent elements of a single-crystal substrate (single-crystal wafer) may contain other substances such as a binder substance for mixing in addition to the constituent elements of the single-crystal substrate (single-crystal wafer). However, even if the polycrystal material contains other substances such as a binder substance, it does not impair the object and effect of the present disclosure. Therefore, polycrystal materials containing other substances such as a binder substance in addition to the constituent elements of the single-crystal substrate (single-crystal wafer) are also considered to be included in the polycrystal material composed of the constituent elements of the single-crystal substrate (single-crystal wafer) in the present disclosure.

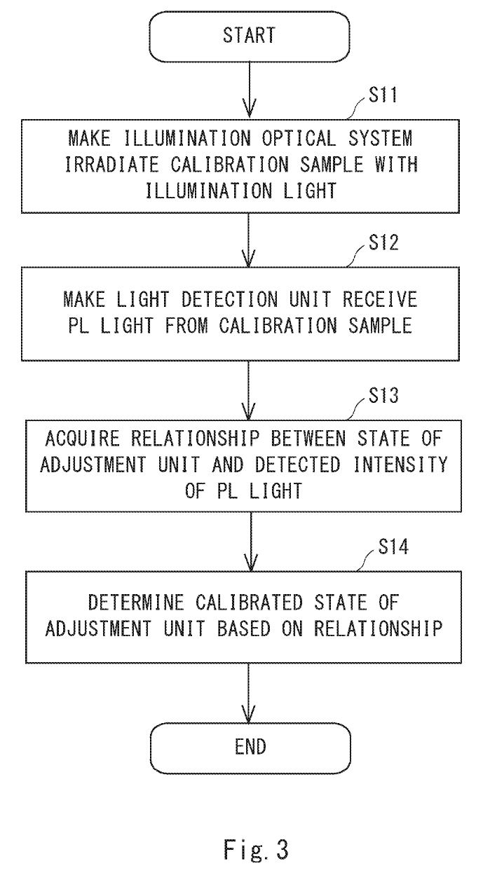

FIG. 3 is a flowchart showing a calibration method for an optical apparatus according to an embodiment. This calibration method can be performed, for example, at a predetermined frequency (e.g., once a day or once every few tens of hours) before the inspection of an object to be inspected using the optical apparatus is started.

The optical apparatus (FIG. 1) includes an illumination optical system including adjustment units (adjustment units 65 and 66) for adjusting the illumination intensity of the illumination light, and light detection units (light detection units 20 and 25) for detecting reaction light based on the illumination light. The optical apparatus evaluates a single-crystal wafer (SiC substrate 16) based on photoluminescence light, which is reaction light generated from the single-crystal wafer (SiC substrate 16) as the optical apparatus irradiates the single-crystal wafer (SiC substrate 16) with the illumination light.

In this calibration method for the optical apparatus, a calibration sample 150 is irradiated with the illumination light by the illumination optical system (S11). The calibration sample 150 may be disposed at a corner of the stage 15.

Next, the light detection unit (first light detection unit 25) is made to receive the photoluminescence light from the calibration sample 150 (S12). A relationship between the state of the adjustment unit (adjustment unit 66) of the illumination optical system and the detected intensity of the photoluminescence light is acquired (S13). A calibrated state of the adjustment unit (e.g., the lamp opening, the power supplied to the lamp) is determined based on this relationship (S14).

Note that the calibration sample 150 is made of a polycrystal material composed of the same elements as those of the base material of the single-crystal wafer (e.g., single-crystal SiC) (i.e., Si and C). Since the calibration sample has the above-described characteristics, proper calibration can be continuously performed over a long time with substantially no deterioration even when the irradiation with the illumination light for the calibration is repeated.

In another embodiment, a method may include placing a sample to be evaluated on a holding part (stage 15) of an optical apparatus, making a second illumination optical system irradiate the sample to be evaluated with second illumination light reflected on a surface of the sample to be evaluated, making a light detection unit (second light detection unit 20) receive reflected light from the sample to be evaluated, acquiring a relationship between output intensity of the second illumination light and detected intensity of the reflected light, and determining a calibrated output of the second illumination light based on the relationship. Making the illumination optical system irradiate the calibration sample with the illumination light (for photoluminescence) may include making the illumination optical system irradiate the calibration sample different from the sample to be evaluated with the illumination light (for photoluminescence) in a state where the sample to be evaluated is placed on the holding part.

In another embodiment, an optical apparatus may include a second illumination optical system capable of irradiating the single-crystal wafer with second illumination light reflected on a surface of the single-crystal wafer, a second light detection unit capable of detecting reflected light from the single-crystal wafer based on the second illumination light, and a second adjustment unit capable of adjusting the illumination intensity of the second illumination light. This calibration method for the optical apparatus may further include placing the single-crystal wafer on the holding part of the optical apparatus; making the second illumination optical system irradiate the single-crystal wafer with the second illumination light; making the second light detection unit receive reflected light from the single-crystal wafer; acquiring a relationship between a state of the second adjustment unit and detected intensity of the reflected light; and determining a calibrated state of the second adjustment unit based on the relationship. Making the illumination optical system irradiate the calibration sample with the illumination light may include making the illumination optical system irradiate the calibration sample with the illumination light in a state where the single-crystal wafer is placed on the holding part. In still another embodiment, the single-crystal wafer may be a single-crystal compound semiconductor wafer.

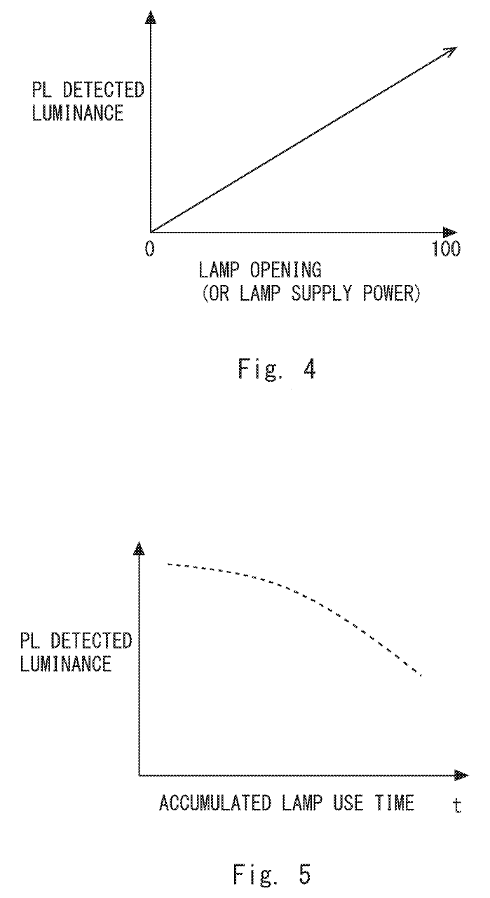

FIG. 4 is a graph showing a relationship between the lamp opening of the illumination light source and the detected intensity of photoluminescence light from the sample (sample to be evaluated or calibration sample) (which is referred to as PL detected luminance).

The horizontal axis indicates the lamp opening, in which lamp opening of 100% means that the lamp is fully opened, and lamp opening of 0% means that the lamp is fully closed. In some embodiments, the lamp opening changes depending on the state of the adjustment unit 65 including a dimmer plate having a plurality of apertures having different sizes, i.e., depending on the position of the adjustment plate (i.e., depending on which of the apertures having different sizes the light passes through).

As shown in FIG. 4, the PL detected luminance is increased by increasing the lamp opening. For example, the PL detected luminance linearly increases as shown in FIG. 4. Note that, in some embodiments, the power supplied to the lamp may be changed in order to change the PL detected luminance. In this case, the horizontal axis of the graph shown in FIG. 4 indicates the power supplied to the lamp, and the intensity of the PL detected luminance is increased by increasing the power supplied to the lamp. In some embodiments, the power supplied to the lamp changes according to the state of the adjustment unit 66 including the controller for controlling the power supplied to the lamp, i.e., according to the target amount of power supplied to the lamp set by the controller.

FIG. 5 is a graph showing a relationship between the cumulative time of the use of the lamp of the illumination light source and the PL detected luminance. The horizontal axis indicates the time (the cumulative time of the use of the lamp), and the vertical axis indicates the PL detected luminance. For example, when a new lamp is continuously used with constant lamp opening (e.g., lamp opening of 70%), the PL detected luminance could gradually decrease according to the cumulative time of the use of the lamp as indicated by a broken curve in FIG. 5 because the intensity of the illumination light decreases due to the mechanical and/or chemical aged deterioration of the lamp that occurs according to the cumulative time of the use of the lamp.

Therefore, in order to obtain PL detected luminance in a predetermined range in the inspection of a sample to be evaluated, it is necessary to adjust the state of the adjustment unit 66 so as to cancel out the decrease in the intensity of the illumination light due to the aged deterioration of the lamp. For example, it is necessary to increase the lamp opening.

Adjusting the state of the adjustment unit so as to obtain PL detected luminance in a predetermined range irrespective of the decrease in the intensity of the illumination light due to the aged deterioration of the lamp as described above is referred to as the calibration of the illumination light.

Although the illumination light source is a lamp in the above description, the intensity of the illumination light also decreases due to the aged deterioration even when a light source other than lamps is used as the light source 50. Therefore, even when a light source such as an LED or a laser is used, the state of the adjustment unit 66 may be adjusted so that the PL detected luminance in the predetermined range is obtained by the first light detection unit 25 irrespective of the deteriorated state of the light source. That is, the calibration of the illumination light may be performed. The adjustment unit 66 in this case may be an adjustment unit 66 including an adjustment plate as described above, or an adjustment unit 66 including a controller for supplying power to the light source 50 belonging to the first illumination optical system.

Further, in the above description, the calibration of the illumination light has been described by using an example in which the state of the adjustment unit 66 is adjusted so that the PL detected luminance in the predetermined range is obtained irrespective of the deteriorated state of the light source 50. However, the calibration of the illumination light may be performed for different purposes depending on the use of the illumination light. For example, the calibration of the illumination light (second illumination light) may be performed so that the reflected light from the surface of the sample to be evaluated (single-crystal SiC substrate) can be detected with intensity (detected luminance) in a predetermined range. That is, adjusting the state of the second adjustment unit 65 so that the detected intensity of the reflected light in the predetermined range can be obtained by the second light detection unit 20 irrespective of the deteriorated state of the light source 50 belonging to the second illumination optical system is also regarded as the calibration of the illumination light. The second adjustment unit 65 in this case may be a second adjustment unit 65 including an adjustment plate as described above, or a second adjustment unit 65 including a controller for supplying power to the light source 50 belonging to the second illumination optical system. In other words, the calibration of the second illumination light can be performed by adjusting the state of the second adjustment unit 65.

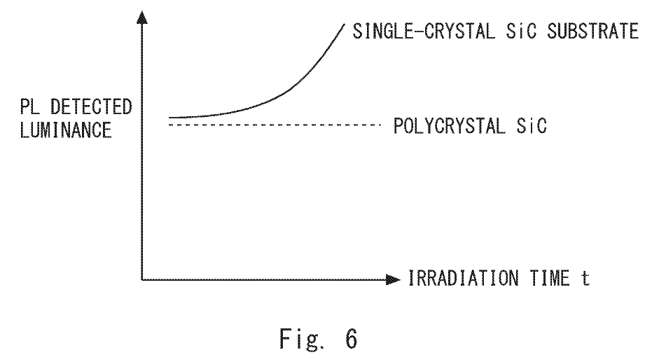

The description will be continued by returning to the calibration of the illumination light related to the PL detected luminance (the calibration of the first illumination light). FIG. 6 shows graphs showing changes of PL detected luminance according to the irradiation time of illumination light (excitation light) of a single-crystal SiC substrate and those of a polycrystal SiC substrate for comparison therebetween. In the case of the single-crystal SiC substrate indicated by a solid curve, an oxide film is formed according to the irradiation of the illumination light (excitation light), so that the PL detected luminance increases according to the accumulation of the irradiation time. In contrast, in the case of the polycrystal SiC indicated by a broken curve, no oxide film is formed irrespective of the irradiation of the illumination light (excitation light), or even if an oxide film is formed, its amount is very small. Therefore, the PL detected luminance is maintained roughly constant irrespective of the accumulation of the irradiation time.

Note that if a sample for which the PL detected luminance changes (it is assumed that the PL detected luminance increases in this example) according to the accumulation of the irradiation time of the illumination light (excitation light) is used as the calibration sample, the following problem occurs. That is, even in the case where the PL detected luminance decreases due to the deterioration of the light source under the normal circumstances, the PL detected luminance is detected higher than the actual luminance when the calibration sample has been used for a relatively long time. Therefore, even when the state of the adjustment unit 66 can be brought into a state where the PL detected luminance when the calibration sample is irradiated with the illumination light falls in the predetermined range (i.e., can be brought into the calibrated state), if the sample to be evaluated is irradiated with the illumination light under this calibrated state, the above-described PL detected luminance in the predetermined range cannot be detected, so that a proper inspection cannot be performed.

Therefore, in this embodiment, the illumination light (first illumination light) is calibrated by using a polycrystal SiC as the calibration sample. According to this embodiment, it is possible to avoid the occurrence of the above-described problem and thereby to properly calibrate the illumination light over a long time.

For the comparison, the calibration of the second illumination light will be described. As described above, by adjusting the state of the second adjustment unit 65, it is possible to detect the reflected light with detected intensity in the predetermined range by the second light detection unit 20 irrespective of the deteriorated state of the light source 50 belonging to the second illumination optical system. Note that, in general, it is unlikely that a single-crystal wafer deteriorates according to the irradiation with the second illumination light. Therefore, the calibration of the second illumination light can be performed by using a single-crystal wafer as the sample to be evaluated. That is, the calibration of the second illumination light may be performed by adjusting the state of the second adjustment unit 65 so that the detected intensity, in the second light detection unit 20, of the reflected light generated from the single-crystal wafer, which is the sample to be evaluated, irradiated with the second illumination light falls in the predetermined range.

In addition, the reflectance of the polycrystal material, which is the sample to be calibrated for the calibration of the first illumination light (excitation light), for the second illumination light could be different from the reflectance of the single-crystal wafer for the second illumination light. Based also on this fact, there seems to be the rationality in performing the calibration of the second illumination light by using a single-crystal wafer as the sample to be evaluated.

Based on the above-described facts, in a state where a single-crystal SiC wafer, which is the sample to be evaluated (object to be inspected), is placed on the stage 15, (1) the calibration of the first illumination light (excitation light) may be performed by irradiating the polycrystal SiC, which is the calibration sample, with the first illumination light (excitation light), and (2) the calibration of the second illumination light may be performed by irradiating the single-crystal SiC wafer, which is the sample to be evaluated, with the second illumination light. In this way, it is possible to eliminate the need to separately prepare a special sample for the calibration of the second illumination light, so that the calibration can be rationalized as a whole.

In some embodiments, the following illumination method performed by an optical apparatus can be provided. That is, an illumination method performed by an optical apparatus includes: an illumination optical system capable of irradiating a single-crystal wafer with illumination light; and a light detection unit capable of detecting photoluminescence light from the single-crystal wafer based on the illumination light. The optical apparatus includes an adjustment unit capable of adjusting illumination intensity of the illumination light. The illumination method may include: making the illumination optical system irradiate a calibration sample with the illumination light; making the light detection unit receive photoluminescence light from the calibration sample; acquiring a relationship between a state of the adjustment unit and detected intensity of the photoluminescence light; determining a calibrated state of the adjustment unit based on the relationship; placing the single-crystal wafer on a holding part of the optical apparatus; making the illumination optical system irradiate the single-crystal wafer with the illumination light under a condition that the adjustment unit is in the calibrated state; making the light detection unit receive photoluminescence light from the single-crystal wafer; and determining a defect in the single-crystal wafer based on a result of detection of the photoluminescence light from the single-crystal wafer. The calibration sample is made of a polycrystal material made of the same element as that of a base material of the single-crystal wafer.

In some embodiments, an optical apparatus may be provided. The optical apparatus includes: an illumination optical system capable of irradiating a single-crystal wafer with illumination light; a light detection unit capable of detecting photoluminescence light from the single-crystal wafer based on the illumination light; an adjustment unit capable of adjusting illumination intensity of the illumination light; and a holding part having a first area in which the single-crystal wafer can be placed and a second area in which a calibration sample can be placed, the second area being provided outside the first area. The calibration sample is made of a polycrystal material made of the same element as that of a base material of the single-crystal wafer. The optical apparatus is configured to make the illumination optical system irradiate the calibration sample with the illumination light; make the light detection unit receive photoluminescence light from the calibration sample; acquire a relationship between a state of the adjustment unit and detected intensity of the photoluminescence light; and determine a calibrated state of the adjustment unit based on the relationship.

In another embodiment, the optical apparatus may be configured to make the illumination optical system irradiate the single-crystal wafer placed in the holding part with the illumination light under a condition that the adjustment unit is in the calibrated state; and may include a determination unit (defect classification determination unit 40) configured to determine a defect in the single-crystal wafer based on a result of detection of photoluminescence light from the single-crystal wafer.

In another embodiment, the optical apparatus includes an illumination optical system capable of irradiating a single-crystal wafer with illumination light; a light detection unit capable of detecting photoluminescence light from the single-crystal wafer based on the illumination light; an adjustment unit capable of adjusting illumination intensity of the illumination light; and a holding part having a first area in which the single-crystal wafer can be placed and a second area in which a calibration sample can be placed, the second area being provided outside the first area. The calibration sample is made of a polycrystal material made of the same element as that of a base material of the single-crystal wafer. The optical apparatus further includes a processor, and a memory configured to store instructions to be executed by the processor. In the optical apparatus, instructions for making the processor to perform a calibration method described below when a single-crystal wafer is placed as the sample to be evaluated in a first area of the holding part (or it is detected by a sensor), when a calibration sample is placed in a second area of the holding part (or it is detected by a sensor), and when a calibration mode is executed by an operation (to an input device) made by an operator, are stored in the memory. The instructions for performing the calibration method include making the illumination optical system irradiate the calibration sample with the illumination light; making the light detection unit receive photoluminescence light from the calibration sample; acquiring a relationship between a state of the adjustment unit and detected intensity of the photoluminescence light; and determining a calibrated state of the adjustment unit based on the relationship.

In another embodiment, a program for an optical apparatus may be provided. The optical apparatus includes: an illumination optical system capable of irradiating a single-crystal wafer with illumination light; a light detection unit capable of detecting photoluminescence light from the single-crystal wafer based on the illumination light; an adjustment unit capable of adjusting illumination intensity of the illumination light; and a holding part having a first area in which the single-crystal wafer can be placed and a second area in which a calibration sample can be placed, the second area being provided outside the first area. The calibration sample is made of a polycrystal material made of the same element as that of a base material of the single-crystal wafer. The program causes, when a single-crystal wafer is placed as the sample to be evaluated in a first area of the holding part (or it is detected by a sensor), when a calibration sample is placed in a second area of the holding part (or it is detected by a sensor), and when a calibration mode is executed by an operation (e.g., to an input device) made by an operator, a computer to perform in the optical apparatus: making the illumination optical system irradiate the calibration sample with the illumination light; making the light detection unit receive photoluminescence light from the calibration sample; acquiring a relationship between a state of the adjustment unit and detected intensity of the photoluminescence light; and determining a calibrated state of the adjustment unit based on the relationship.

In some of the examples described above, the execution of the calibration mode may be started, instead of or in addition to the operation made by an operator, under at least one of the following conditions: the time elapsed from the previous execution of the calibration mode meets a predetermined condition; the number of samples to be evaluated after the previous execution of the calibration mode meets a predetermined condition; and the cumulative time or the number of times of irradiation of the illumination light from the previous execution of the calibration mode meets a predetermined condition.

In the examples described above, the program includes instructions (or software code) for, upon loaded into a computer, making the computer perform one or more functions described in the embodiments. The program may be stored in a non-transitory computer readable medium or a tangible storage medium. By way of example and not a limitation, the non-transitory computer readable media or tangible storage media can include a RAM (Random-Access Memory), a ROM (Read-Only Memory), a flash memory, an SSD (Solid-State Drive) or other types of memory technologies, a CD-ROM, a DVD (Digital Versatile Disc), a Blu-ray (Registered Trademark) disc or other types of optical disc storage, and magnetic cassettes, magnetic tape, magnetic disk storage or other types of magnetic storage devices. The program may be transmitted on a transitory computer readable medium or a communication medium. By way of example and not a limitation, the transitory computer readable media or communication media can include electrical, optical, acoustical, or other forms of propagation signals.

Although embodiments according to the present disclosure have been described above, the present disclosure includes modifications that do not impair the objects and advantages of the disclosure and is not limited by the above-described embodiments. The adjustment unit 66 and the second adjustment unit 65 are not limited to adjustment plates and controllers for power supply as long as they can adjust the illumination intensity of the illumination light. The adjustment unit (65 and 66) may be implemented by an optical element(s) such as a diaphragm, a filter, a wave plate, a polarizing plate, a diffraction grating, a mirror, and a lens, and the adjustment unit (65 and 66) may be capable of adjusting the illumination intensity of the illumination light by changing the state, the position, the posture, and/or the combination of optical elements. Some of the components/structures of the embodiments may be omitted as appropriate. For example, the second illumination system, the second adjustment unit 65, and the second light detection unit 20 may be omitted as appropriate according to the purpose of the optical apparatus. Further, some or all of the plurality of embodiments may be combined with another embodiment to form another type of embodiment.

The first and second embodiments can be combined as desirable by one of ordinary skill in the art.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A calibration method for an optical apparatus comprising an illumination optical system capable of irradiating a single-crystal wafer with illumination light, and a light detection unit capable of detecting photoluminescence light from the single-crystal wafer based on the illumination light, wherein:
the optical apparatus comprises an adjustment unit capable of adjusting illumination intensity of the illumination light,
the calibration method comprises:
making the illumination optical system irradiate a calibration sample with the illumination light;
making the light detection unit receive photoluminescence light from the calibration sample;
acquiring a relationship between a state of the adjustment unit and detected intensity of the photoluminescence light; and
determining a calibrated state of the adjustment unit based on the relationship, and
the calibration sample is made of a polycrystal material made of the same element as that of a base material of the single-crystal wafer.

2. The calibration method according to claim 1, wherein:
the optical apparatus comprises:
a second illumination optical system capable of irradiating the single-crystal wafer with second illumination light reflected on a surface of the single-crystal wafer;
a second light detection unit capable of detecting reflected light from the single-crystal wafer based on the second illumination light; and
a second adjustment unit capable of adjusting the illumination intensity of the second illumination light,
the calibration method further comprises:
placing the single-crystal wafer on a holding part of the optical apparatus;
making the second illumination optical system irradiate the single-crystal wafer with the second illumination light;
making the second light detection unit receive the reflected light from the single-crystal wafer;
acquiring a relationship between a state of the second adjustment unit and detected intensity of the reflected light; and
determining a calibrated state of the second adjustment unit based on the relationship, and
making the illumination optical system irradiate the calibration sample with the illumination light includes making the illumination optical system irradiate the calibration sample with the illumination light in a state where the single-crystal wafer is placed on the holding part.

3. The calibration method according to claim 1, wherein the single-crystal wafer is a single-crystal compound semiconductor wafer.

4. An illumination method performed by an optical apparatus comprising an illumination optical system capable of irradiating a single-crystal wafer with illumination light, and a light detection unit capable of detecting photoluminescence light from the single-crystal wafer based on the illumination light, wherein:
the optical apparatus comprises an adjustment unit capable of adjusting illumination intensity of the illumination light,
the illumination method comprises:
making the illumination optical system irradiate a calibration sample with the illumination light;
making the light detection unit receive photoluminescence light from the calibration sample;
acquiring a relationship between a state of the adjustment unit and detected intensity of the photoluminescence light;
determining a calibrated state of the adjustment unit based on the relationship;
placing the single-crystal wafer on a holding part of the optical apparatus;
making the illumination optical system irradiate the single-crystal wafer with the illumination light under a condition that the adjustment unit is in the calibrated state;
making the light detection unit receive photoluminescence light from the single-crystal wafer; and
determining a defect in the single-crystal wafer based on a result of detection of the photoluminescence light from the single-crystal wafer, and
the calibration sample is made of a polycrystal material made of the same element as that of a base material of the single-crystal wafer.

5. The illumination method according to claim 4, wherein:
the optical apparatus comprises:
a second illumination optical system capable of irradiating the single-crystal wafer with second illumination light reflected on a surface of the single-crystal wafer;
a second light detection unit capable of detecting reflected light from the single-crystal wafer based on the second illumination light; and
a second adjustment unit capable of adjusting the illumination intensity of the second illumination light,
the illumination method further comprises:
making the second illumination optical system irradiate the single-crystal wafer with the second illumination light;
making the second light detection unit receive the reflected light from the single-crystal wafer;
acquiring a relationship between a state of the second adjustment unit and detected intensity of the reflected light;
determining a calibrated state of the second adjustment unit based on the relationship; and
making the second illumination optical system irradiate the single-crystal wafer with the second illumination light under a condition that the second adjustment unit is in the calibrated state, and
determining a defect in the single-crystal wafer includes determining a defect in the single-crystal wafer based on a result of detection of the photoluminescence light from the single-crystal wafer and a result of detection of the reflected light from the single-crystal wafer.

6. An optical apparatus comprising:
an illumination optical system capable of irradiating a single-crystal wafer with illumination light;
a light detection unit capable of detecting photoluminescence light from the single-crystal wafer based on the illumination light;
an adjustment unit capable of adjusting illumination intensity of the illumination light; and
a holding part having a first area in which the single-crystal wafer can be placed and a second area in which a calibration sample can be placed, the second area being provided outside the first area,
wherein the calibration sample is made of a polycrystal material made of the same element as that of a base material of the single-crystal wafer, and
wherein the optical apparatus is configured to:
make the illumination optical system irradiate the calibration sample with the illumination light;
make the light detection unit receive photoluminescence light from the calibration sample;
acquire a relationship between a state of the adjustment unit and detected intensity of the photoluminescence light; and
determine a calibrated state of the adjustment unit based on the relationship.

7. The optical apparatus according to claim 6, wherein:
the illumination optical system is configured to irradiate the single-crystal wafer placed on the holding part with the illumination light under a condition that the adjustment unit is in the calibrated state, and
the optical apparatus further comprises a determination unit configured to determine a defect in the single-crystal wafer based on a result of detection of the photoluminescence light from the single-crystal wafer.
